(19) United States
(12) Patent Application Publication
(10) Pub. No.: US 2012/0031125 A1
(43) Pub. Date: Feb. 9, 2012

(54) ENERGY-SAVING SYSTEM AND CONTAINER DATA CENTER INCLUDING THE SAME

(75) Inventor: YAO-TING CHANG, Tu-Cheng (TW)

(73) Assignee: HON HAI PRECISION INDUSTRY CO., LTD., Tu-Cheng (TW)

(21) Appl. No.: 12/871,941

(22) Filed: Aug. 31, 2010

(30) Foreign Application Priority Data
Aug. 4, 2010 (TW) 99125832

(51) Int. Cl. F25B 49/00; H05K 5/02

(52) U.S. Cl. 62/126; 454/184

(57) ABSTRACT

An energy-saving system includes first and second infrared emitters, first and second infrared receivers, an air conditioner, and a controller. The infrared receivers send out detecting signals when the infrared receivers do not receive infrared signals of the infrared emitters. The controller controls the air conditioner to adjust temperature in a container data center according to the order of receiving the detecting signals of the first infrared receiver and the second infrared receiver.

### BACKGROUND

1. Technical Field

The present disclosure relates to an energy-saving system and a container data center including the energy-saving system.

2. Description of Related Art

Keeping the temperature below 35 degrees Celsius (° C.) in a container data center helps electronic apparatuses therein work normally. To make a container data center comfortable for users, the temperature inside is always controlled between 18° C.-27° C. However, this temperature is still maintained even after the users have left the container data center. Therefore, the energy is being wasted.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a block diagram of an exemplary embodiment of an energy-saving system.

FIG. 2 is an isometric view of an exemplary embodiment of a container data center including the energy-saving system of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

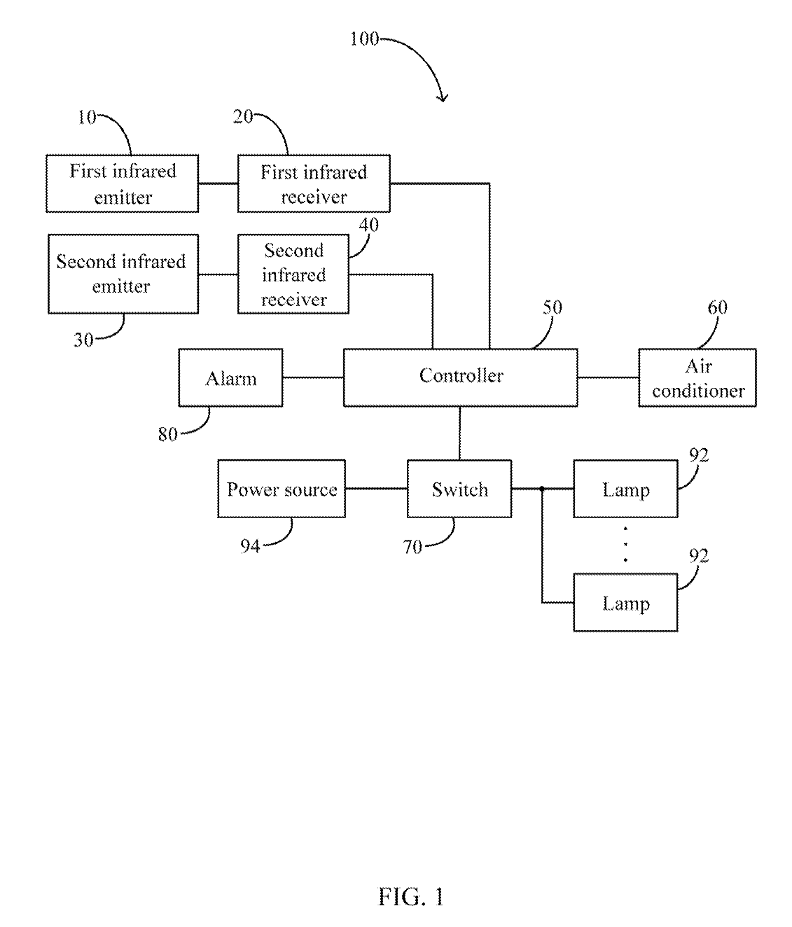

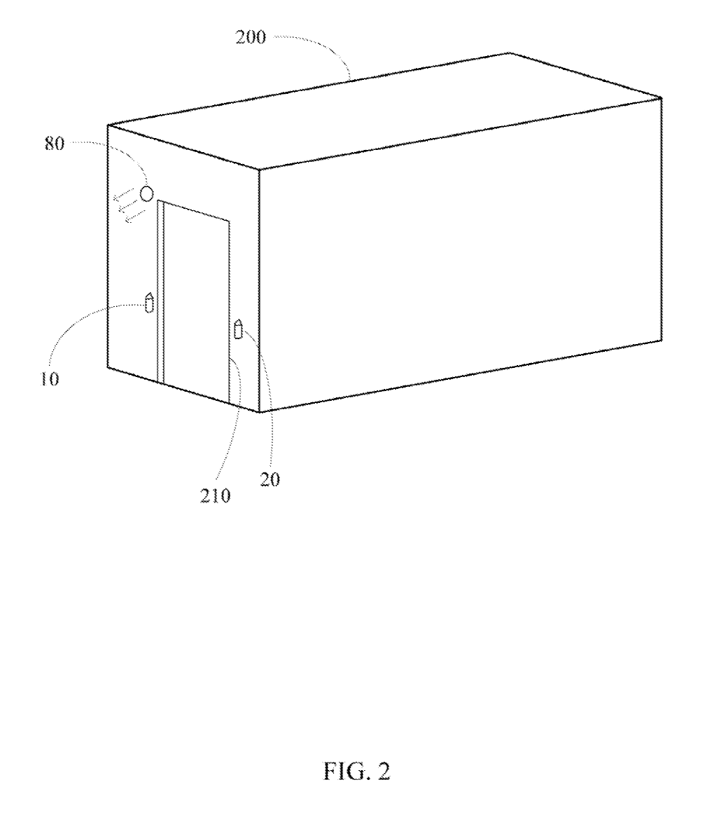

Referring to FIGS. 1 and 2, an exemplary embodiment of an energy-saving system 100 includes a first infrared emitter 10, a first infrared receiver 20, a second infrared emitter 30, a second infrared receiver 40, a controller 50, an air conditioner 60, a switch 70, an alarm 80, a number of lamps 92, and a power source 94.

The first and second infrared emitters 10 and 30 emit infrared signals. The first infrared receiver 20 receives the infrared signal of the first infrared emitter 10. The second infrared receiver 40 receives the infrared signal of the second infrared emitter 30.

The first infrared emitter 10 and the first infrared receiver 20 are mounted on an external surface of the frame of a door 210 of a container data center 200. The second infrared emitter 30 and the second infrared receiver 40 are mounted substantially opposite on an internal surface of the frame of the door 210.

The height on the door 210 of the infrared emitters 10 and 30, and the infrared receivers 20 and 40 may range from about 120 centimeters (cm) to about 150 cm. When a user stands between the first infrared emitter 10 and the first infrared receiver 20 or between the second infrared emitter 30 and the second infrared receiver 40, the first infrared receiver 20 or the second infrared receiver 40 cannot receive the corresponding infrared signal.

The first infrared receiver 20 sends out a detecting signal when the first infrared receiver 20 does not receive the infrared signal of the first infrared emitter 10. The second infrared receiver 40 sends out a detecting signal when the second infrared receiver 40 does not receive the infrared signal of the second infrared emitter 30.

The controller 50 is connected to the first infrared receiver 20, the second infrared receiver 40, the air conditioner 60, and the alarm 80. The controller 50 determines whether the user enters or exits from the container data center 200 through the door 210 according to the order of receiving the detecting signals of the infrared receivers 20 and 40. For example, when the controller 50 receives the detecting signal of the first infrared receiver 20 before receiving the detecting signal of the second infrared receiver 40, the controller 50 determines that the user enters the container data center 200.

A first terminal of the switch 70 is connected to the power source 94. A second terminal of the switch 70 is connected to the lamps 92. A third terminal of the switch 70 is connected to the controller 50.

The air conditioner 60, the lamps 92, and the power source 94 are mounted in the container data center 200. The air conditioner 60 is used to cool the air in the container data center 200. The power source 94 supplies power to the lamps 92.

The alarm 80 is mounted on an outer surface of the container data center 200. In the embodiment, the alarm 80 can emit red and green lights.

The user has to close the door 210 after entering or exiting from the container data center 200, to prevent the cool air from escaping out of the container data center 200.

When the user enters the container data center 200, the user passes between the first infrared emitter 10 and the first infrared receiver 20 before passing through the second infrared emitter 30 and the second infrared receiver 40. The controller 50 receives the detecting signal of the first infrared receiver 20 before receiving the detecting signal of the second infrared receiver 40. The controller 50 determines that a user has entered the container data center 200.

The controller 50 controls the air conditioner 60 to adjust the temperature to range from about 18° degrees Celsius (° C.) to about 27° C., and controls the alarm 80 to emit red light. At the same time, the controller 50 controls the switch 70 to connect the power source 94 to the lamps 92 to turn on the lamps 92 if the lamps were off.

When the user exits from the container data center 200, the user passes between the second infrared emitter 30 and the second infrared receiver 40 before passing between the first infrared emitter 10 and the first infrared receiver 20. The controller 50 receives the detecting signal of the second infrared receiver 40 before receiving the detecting signal of the first infrared receiver 20. The controller 50 determines that the user has exited from the container data center 200.

The controller 50 controls the air conditioner 60 to adjust the temperature to a range from about 27° C. to about 35° C., and controls the alarm 80 to emit green light. At the same time, the controller 50 controls the switch 70 to disconnect the power source 94 from the lamps 92 to turn off the lamps 92.

In other embodiments, the alarm 80 is a buzzer. The buzzer buzzes when the user enters the container data center 200.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. An energy-saving system, comprising:
a first infrared emitter;
a first infrared receiver, wherein the first infrared emitter and the first infrared receiver are mounted on an external surface of the frame of a door of a container data center;
a second infrared emitter;
a second infrared receiver, wherein the second infrared emitter and the second infrared receiver are mounted on an internal surface of the frame of the door, wherein the first and second infrared receivers send out detecting signals when the first and second infrared receivers do not receive the corresponding infrared signals of the first and second infrared emitters;
an air conditioner adjusting the temperature in the container data center; and
a controller connected to the first infrared receiver, the second infrared receiver, and the air conditioner, wherein the controller receives the detecting signals of the first and second infrared receivers and controls the air conditioner to adjust the temperature according to the order of receiving the detecting signals of the first infrared receiver and the second infrared receiver.

2. The energy-saving system of claim 1, wherein the controller controls the air conditioner to adjust the temperature to be a first value if the controller receives the detecting signal of the first infrared receiver before receiving the detecting signal of the second infrared receiver, the controller controls the air conditioner to adjust the temperature to be a second value if the controller receives the detecting signal of the second infrared receiver before receiving the detecting signal of the first infrared receiver.

3. The energy-saving system of claim 1, wherein a height of the first and second infrared emitters and the first and second infrared receivers range from about 120 centimeters (cm) to about 150 cm.

4. The energy-saving system of claim 1, further comprising a switch, a number of lamps, and a power source, wherein a first terminal of the switch is connected to the power source, a second terminal of the switch is connected to the lamps, a third terminal of the switch is connected to the controller, the controller controls the switch to connect or disconnect the power source to or from the lamps according to the order of receiving the detecting signals of the first infrared receiver and the second infrared receiver.

5. The energy-saving system of claim 4, wherein the controller controls the switch to connect the power source to the lamps if the controller receives the detecting signal of the first infrared receiver before receiving the detecting signal of the second infrared receiver, the controller controls the switch to disconnect the power source from the lamps if the controller receives the detecting signal of the second infrared receiver before receiving the detecting signal of the first infrared receiver.

6. The energy-saving system of claim 1, further comprising an alarm connected to the controller, wherein the controller controls the alarm to emit red or green light according to the order of receiving the detecting signals of the first infrared receiver and the second infrared receiver.

7. The energy-saving system of claim 6, wherein the controller controls the alarm to emit red light if the controller receives the detecting signal of the first infrared receiver before receiving the detecting signal of the second infrared receiver, the controller controls the alarm to emit green light if the controller receives the detecting signal of the second infrared receiver before receiving the detecting signal of the first infrared receiver.

8. The energy-saving system of claim 1, further comprising a buzzer connected to the controller, wherein the controller controls the buzzer to buzz if the controller receives the detecting signal of the first infrared receiver before receiving the detecting signal of the second infrared receiver.

9. A container data center, comprising an energy-saving system, wherein the energy-saving system comprises:
a first infrared emitter;
a first infrared receiver, wherein the first infrared emitter and the first infrared receiver are mounted on an external surface of the frame of a door of a container data center;
a second infrared emitter;
a second infrared receiver, wherein the second infrared emitter and the second infrared receiver are mounted on an internal surface of the frame of the door, wherein the first and second infrared receivers send out detecting signals when the first and second infrared receivers do not receive the corresponding infrared signals of the first and second infrared emitters;
an air conditioner adjusting the temperature in the container data center; and
a controller connected to the first infrared receiver, the second infrared receiver, and the air conditioner, wherein the controller receives the detecting signals of the first and second infrared receivers and controls the air conditioner to adjust the temperature according to the order of receiving the detecting signals of the first infrared receiver and the second infrared receiver.

10. The container data center of claim 9, wherein the controller controls the air conditioner to adjust the temperature to be a first value if the controller receives the detecting signal of the first infrared receiver before receiving the detecting signal of the second infrared receiver, the controller controls the air conditioner to adjust the temperature to be a second value if the controller receives the detecting signal of the second infrared receiver before receiving the detecting signal of the first infrared receiver.

11. The container data center of claim 9, wherein the height of the first and second infrared emitters and the first and second infrared receivers range from about 120 centimeters (cm) to about 150 cm.

12. The container data center of claim 9, wherein the energy-saving system further comprises a switch, a number of lamps, and a power source, wherein a first terminal of the switch is connected to the power source, a second terminal of the switch is connected to the lamps, a third terminal of the switch is connected to the controller, the controller controls the switch to connect or disconnect the power source to or from the lamps according to the order of receiving the detecting signals of the first infrared receiver and the second infrared receiver.

13. The container data center of claim 12, wherein the controller controls the switch to connect the power source to the lamps if the controller receives the detecting signal of the first infrared receiver before receiving the detecting signal of the second infrared receiver, the controller controls the switch to disconnect the power source from the lamps if the controller receives the detecting signal of the second infrared receiver before receiving the detecting signal of the first infrared receiver.

14. The container data center of claim 9, wherein the energy-saving system further comprises an alarm connected to the controller, the controller controls the alarm to emit red or green light according to the order of receiving the detecting signals of the first infrared receiver and the second infrared receiver.

15. The container data center of claim 14, wherein the controller controls the alarm to emit red light if the controller receives the detecting signal of the first infrared receiver before receiving the detecting signal of the second infrared receiver, the controller controls the alarm to emit green light if the controller receives the detecting signal of the second infrared receiver before receiving the detecting signal of the first infrared receiver.

16. The container data center of claim 9, wherein the energy-saving system further comprises a buzzer connected to the controller, the controller controls the buzzer to work if the controller receives the detecting signal of the first infrared receiver before receiving the detecting signal of the second infrared receiver.
